(19) United States
(12) Patent Application Publication
(10) Pub. No.: US 2024/0183910 A1
(43) Pub. Date: Jun. 6, 2024

(54) MEASURING DEVICE, DIAGNOSTIC SYSTEM INCLUDING THE SAME, AND DIAGNOSTIC METHOD USING THE SAME

(71) Applicant: SAMSUNG SDI CO., LTD., Yongin-si (KR)

(72) Inventor: Songyi PARK, Yongin-si (KR)

(21) Appl. No.: 18/496,565

(22) Filed: Oct. 27, 2023

(30) Foreign Application Priority Data
Dec. 6, 2022 (KR) 10-2022-0169003

(51) Int. Cl. G01R 31/3835; H01M 10/42; H01M 10/48

(52) U.S. Cl. CPC G01R 31/3835; H01M 10/425; H01M 10/486; H01M 2010/4271

(57) ABSTRACT

A measuring device includes: a voltage measurer configured to measure a voltage from a node on a wire connected to a battery management system (BMS); and a controller configured to receive the measured voltage signal from the voltage measurer to derive a voltage value, to count the number of times the voltage value reaches a reference voltage during a measuring period, and to determine a state of the BMS as one of a normal state of a first mode, a normal state of a second mode, or an abnormal state based on the number of times.

### CROSS-REFERENCE TO RELATED APPLICATION

The present application claims priority to and the benefit of Korean Patent Application No. 10-2022-0169003 filed in the Korean Intellectual Property Office on Dec. 06, 2022, the entire content of which is incorporated herein by reference.

### BACKGROUND

### 1. Field

Aspects of some embodiments of the present disclosure relate to a measuring device, a diagnostic system including the same, and a diagnostic method using the same.

### 2. Description of the Related Art

In a battery system, a battery management system (BMS) may be divided into several modes according to a cycle of measuring a voltage, a current, a temperature, and the like.

The measuring cycle of the BMS may be used as an indicator for diagnosing whether the BMS is operating normally. However, in order to check the measuring cycle of the BMS, efforts such as displaying a specific signal on a screen by using equipment such as an oscilloscope and manipulating the screen and the equipment are required, and the work therefore may take excessive time.

The above information disclosed in this Background section is only for enhancement of understanding of the background and therefore the information discussed in this Background section does not necessarily constitute prior art.

### SUMMARY

Aspects of some embodiments of the present disclosure include a measuring device that may check a measuring cycle of a BMS.

Aspects of some embodiments include a diagnostic system and a diagnostic method that may diagnose whether or not a BMS is operating normally based on a measuring cycle of the BMS.

Aspects of some embodiments of the present disclosure include a measuring device, including: a voltage measurer measuring a voltage from a node on a wire connected to a battery management system (BMS); and a controller that receives the measured voltage signal from the voltage measurer to derive a voltage value, counts the number of times the voltage value reaches a reference voltage during a measuring period, and determines a state of the BMS as one of a normal state of a first mode, a normal state of a second mode, and/or an abnormal state based on the number of times.

According to some embodiments, the wire may be a wire connected to one end of a thermistor. The first mode is a power mode in which the BMS measures a temperature from the thermistor at a cycle of a first period. The second mode is a power mode in which the BMS measures the temperature from the thermistor at a cycle of a second period longer than the first period.

According to some embodiments, when the number of times is within a first range in which a value obtained by dividing the measuring period by the first period and multiplied by 2 is a minimum value and a value obtained by adding 2 to the minimum value is a maximum value, the controller may determine the state of the BMS as the normal state of the first mode.

According to some embodiments, when the number of times is within a second range in which a value obtained by dividing the measuring period by the second period and multiplied by 2 is a minimum value and a value obtained by adding 2 to the minimum value is a maximum value, the controller may determine the state of the BMS as the normal state of the second mode.

According to some embodiments, the controller may determine the state of the BMS as the abnormal state when the number is not within the first and second ranges.

According to some embodiments of the present disclosure a diagnostic system includes: a measuring device that measures a voltage from a node on a wire connected to a battery management system (BMS), derives a voltage value from the measured voltage signal, counts the number of times the voltage value reaches a reference voltage during a measuring period, and determines a state of the BMS as one of a normal state of a first mode, a normal state of a second mode, and/or an abnormal state based on the number of times; and an output device that receives a signal indicating the state of the BMS from the measuring device, and outputs a diagnostic result including the state of the BMS based on the signal indicating the state of the BMS.

According to some embodiments, the wire may be a wire connected to one end of a thermistor. The first mode is a power mode in which the BMS measures a temperature from the thermistor at a cycle of a first period. The second mode is a power mode in which the BMS measures the temperature from the thermistor at a cycle of a second period longer than the first period.

According to some embodiments, when the number of times is within a first range in which a value obtained by dividing the measuring period by the first period and multiplied by 2 is a minimum value and a value obtained by adding 2 to the minimum value is a maximum value, the measuring device may determine the state of the BMS as the normal state of the first mode.

According to some embodiments, when the number of times is within a second range in which a value obtained by dividing the measuring period by the second period and multiplied by 2 is a minimum value and a value obtained by adding 2 to the minimum value is a maximum value, the measuring device may determine the state of the BMS as the normal state of the second mode.

According to some embodiments, the measuring device may determine the state of the BMS as the abnormal state when the number is not within the first and second ranges.

According to some embodiments, the output device may include a display that visually outputs the diagnostic result.

According to some embodiments of the present disclosure, a diagnostic method includes: measuring a voltage from a node on a wire connected to a battery management system (BMS); deriving a voltage value based on the measured voltage and counting the number of times the voltage value reaches a reference voltage during a measuring period; determining whether the number of times is within a first or second range; and determining the state of the BMS as one of a normal state of a first mode, a normal state of a second mode, and/or an abnormal state based on the determined result.

According to some embodiments, the wire may be a wire connected to one end of a thermistor. The first mode is a power mode in which the BMS measures a temperature from the thermistor at a cycle of a first period. The second mode is a power mode in which the BMS measures the temperature from the thermistor at a cycle of a second period longer than the first period.

According to some embodiments, the first range may be a range in which a value obtained by dividing the measuring period by the first period and multiplied by 2 is a minimum value and a value obtained by adding 2 to the minimum value is a maximum value.

According to some embodiments, the determining of the state of the BMS as one of the normal state of the first mode, the normal state of the second mode, and the abnormal state: may include determining, when the number of times is within the first range, the state of the BMS as the normal state of the first mode.

According to some embodiments, the second range may be a range in which a value obtained by dividing the measuring period by the second period and multiplied by 2 is a minimum value and a value obtained by adding 2 to the minimum value is a maximum value.

According to some embodiments, the determining of the state of the BMS as one of the normal state of the first mode, the normal state of the second mode, and the abnormal state: may include determining, when the number of times is within the second range, the state of the BMS as the normal state of the second mode.

According to some embodiments, the determining of the state of the BMS as one of the normal state of the first mode, the normal state of the second mode, and the abnormal state may include determining the state of the BMS as the abnormal state when the number is not within the first and second ranges.

According to some embodiments, the diagnostic method may further include outputting a diagnostic result including the state of the BMS determined as one of the normal state of the first mode, the normal state of the second mode, and the abnormal state.

According to some embodiments, the outputting of the diagnostic result may include visually outputting the state of the BMS and the number of times through a display.

According to some embodiments of the present disclosure, it may be possible to diagnose whether or not a BMS operates normally by checking a measuring cycle of the BMS.

According to some embodiments of the present disclosure, it may be possible to improve accuracy of mode determination by determining a power mode of a BMS based on a measuring cycle of the BMS.

### BRIEF DESCRIPTION OF THE DRAWINGS

FIG. 1 illustrates a block diagram of a diagnostic system according to some embodiments.

FIG. 2 is a block diagram for explaining a battery system to which a voltage measurer of FIG. 1 is connected according to some embodiments.

FIG. 3 illustrates a flowchart of a diagnostic method according to some embodiments.

FIG. 4 and FIG. 5 illustrate waveform diagrams of voltage signals derived by a controller in step S2 according to some embodiments.

### DETAILED DESCRIPTION

Hereinafter, aspects of some embodiments disclosed in the present specification will be described in more detail with reference to the accompanying drawings, and in the present specification, the same or similar constituent elements will be denoted by the same or similar reference numerals, and a redundant description thereof will be omitted. The terms “module” and/or “unit, portion, or part” representing constituent element used in the following description are used only in order to make understanding of the specification easier, and thus, these terms do not have meanings or roles that distinguish them from each other by themselves. In addition, in describing embodiments of the present specification, when it is determined that a detailed description of the well-known art associated with the present disclosure may obscure the gist of the present disclosure, it will be omitted. Further, the accompanying drawings are provided only in order to allow embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

Terms including ordinal numbers such as first, second, and the like will be used only to describe various constituent elements, and are not to be interpreted as limiting these constituent elements. The terms are only used to differentiate one constituent element from other constituent elements.

In the present application, it should be understood that the term “include”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance.

A program implemented as a set of instructions embodying a control algorithm necessary for controlling another component may be installed in a component for controlling another component under a specific control condition among components according to some embodiments. A control component may generate output data by processing input data and stored data according to the installed program. The control component may include a non-volatile memory for storing a program and a memory for storing data.

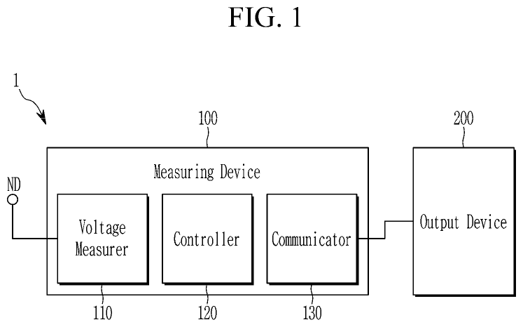

FIG. 1 illustrates a block diagram of a diagnostic system according to some embodiments.

Referring to FIG. 1, a system 1 (hereinafter referred to as a “diagnostic system”) for diagnosing a battery management system (BMS) is connected to a battery system including the BMS to measures a voltage at a connected node, diagnoses a state of the BMS based on the measured voltage value, and outputs a screen displaying the diagnosed result. The diagnostic system 1 may include a measuring device 100 and an output device 200.

The measuring device 100 may measure a voltage at a node ND, and may transmit a result of diagnosing the state of the BMS based on the measured voltage to the output device 200. Here, the node ND may be a node on a wire connected to the BMS. The measuring device 100 may include a voltage measurer 110, a controller 120, and a communicator 130.

The voltage measurer 110 may measure a voltage from the node ND, and may generate a signal (hereinafter referred to as a “voltage signal”) representing the measured voltage to transmit it to the controller 120.

The controller 120 may derive a voltage value based on the voltage signal received from the voltage measurer 110. Deriving the voltage value may comprise the step of outputting a voltage value that has a positive level at the times when a voltage signal is measured at the node ND. The controller 120 may determine whether or not the voltage value reaches a trigger level (e.g., a threshold value) indicating a reference voltage (e.g., a set or predetermined reference voltage) during a measuring period (e.g., a set or predetermined measuring period), may count the number of times the voltage value reaches the trigger level (for example, determine the number of times the voltage value crosses the trigger level), and may determine a state of the BMS based on a count result for the measuring period (e.g., the set or predetermined measuring period). For example, the measuring period (e.g., the set or predetermined measuring period) may be 10 seconds.

The state of the BMS may be either a normal state indicating a normally operating state or an abnormal state indicating a non-normal operating state. The normal state may be a normal state of one of a plurality of power modes according to a cycle in which the BMS measures a voltage, a temperature, a current, and the like of the battery. Hereinafter, for convenience of description, it is assumed that the plurality of power modes are modes according to a cycle in which the BMS measures the temperature of the battery through a thermistor.

According to some embodiments, the plurality of power modes may include a first mode and a second mode. The first mode is a mode in which the BMS periodically measures the temperature through the thermistor every first period. That is, in the first mode, the BMS may repeat an operation of measuring the temperature through the thermistor at a time interval of the first period. The first mode may be referred to as an active mode or a normal mode. The second mode is a mode in which the BMS periodically measures the temperature through the thermistor every second period. That is, in the second mode, the BMS may repeat an operation of measuring the temperature through the thermistor at a time interval of the second period. The second mode may be referred to as a sleep mode or a standby mode. Here, the second period may be longer than the first period. For example, the first period may be 1 second, and the second period may be 10 seconds.

According to some embodiments, the controller 120 may determine the state of the BMS as a normal state in the first mode, a normal state in the second mode, or an abnormal state based on the count result.

For example, the controller 120 may determine a first range in which a value obtained by dividing a measuring period (e.g., a set or predetermined measuring period) by the first period and multiplied by 2 is taken as a minimum value, and a value obtained by adding 2 to the minimum value is taken as a maximum value; and when the count result during the measuring period (e.g., the set or predetermined measuring period) is within the first range, the controller 120 may determine the state of the BMS as a normal state in the first mode in which the voltage measuring cycle is the first period. The controller 120 may determine a second range in which a value obtained by dividing a measuring period (e.g., a set or predetermined measuring period) by the second period and multiplied by 2 is taken as a minimum value, and a value obtained by adding 2 to the minimum value is taken as a maximum value; and when the count result during the measuring period (e.g., the set or predetermined measuring period) is within the second range, the controller 120 may determine the state of the BMS as a normal state in the second mode in which the voltage measuring cycle is the second period. The controller 120 may determine the state of the BMS as the abnormal state when the count result during the measuring period (e.g., the set or predetermined measuring period) is not within the first range or the second range.

The communicator 130 may transmit and receive signals to and from an external device such as the output device 200 through wired or wireless communication with the external device.

The output device 200 may output a diagnosed result based on the signal received from the measurer 100. The output device 200 may include a display that visually outputs the diagnosed result. In addition, the output device may include a speaker that outputs the diagnosed result as sound. The diagnosed result may include information indicating the number of times the voltage value measured by the measurer 100 reaches the trigger level and/or the state of the BMS.

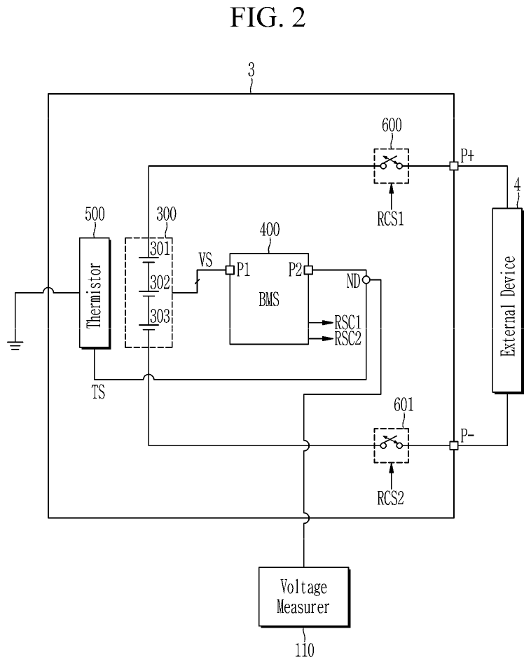

Hereinafter, a state in which the diagnostic system 1 is connected to a wire connected to a BMS will be described in more detail with reference to FIG. 2.

FIG. 2 is a block diagram for explaining a battery system to which the voltage measurer of FIG. 1 is connected.

A battery system 3 may include a battery pack 300, a BMS 400, a thermistor 500, and relays 600 and 601.

An external device 4 may include a load such as an inverter and a converter, and/or a charging device. When the external device 4 is a charger, respective ends of the battery system 3 are connected to the charger, so that the battery system 3 may be charged by receiving power from the charger. When the external device 4 is a load, respective ends of the battery system 3 are connected to the load, so that power supplied by the battery pack 300 may be discharged through the load.

The battery pack 300 may generate a voltage measuring signal VS indicating a cell voltage of each of a plurality of battery cells 301 to 303 to transmit it to the BMS 400. The BMS 400 may obtain a voltage measuring signal VS from the battery pack 300 through a pin P1.

The battery pack 300 may include a plurality of battery cells 301 to 303. Although FIG. 2 illustrates that the number of a plurality of battery cells 301 to 303 is three, embodiments according to the present disclosure are not limited thereto, and the battery pack 300 may be implemented with 2 or more battery cells connected in series, a plurality of battery cells in which two or more battery cells connected in parallel are connected in series, or two or more battery cells connected in parallel.

The thermistor 500 may sense the pack temperature of the battery pack 300 to generate a temperature measuring signal TS, and may transmit the temperature measuring signal TS to the BMS 400. Here, the temperature measuring signal TS may indicate a voltage value determined according to the measured temperature. One end of the thermistor 500 is connected to pin P2, and the other end of the thermistor 500 is connected to the ground. The BMS 400 may obtain the temperature measuring signal TS from the thermistor 500 through a pin P2.

One end of each of the relays 600 and 601 is connected to the battery pack 300, and the other end of each of the relays 600 and 601 is connected to at least one component of an external device 4. Closing and opening of the relays 600 and 601 may be controlled according to relay control signals RCS1 and RCS2 supplied from the BMS 400.

The node ND may be located on a wire connected between one end of the thermistor 500 and the pin P2. The voltage measurer 110 may be electrically connected to the node ND to measure the voltage of the node ND, and may generate a voltage signal representing the measured voltage.

The BMS 400 may periodically receive the temperature measuring signal TS according to a measuring cycle (e.g., a set or predetermined measuring cycle). The measuring cycle (e.g., the set or predetermined measuring cycle) may be determined according to the state of the BMS 400. The measuring cycle (e.g., the set or predetermined measuring cycle) may include the first period in the first mode, the second period in the second mode, and the like.

When the BMS 400 performs an operation of reading the temperature measuring signal TS from the thermistor 500 through the pin P2, the voltage of the node ND may be changed. The voltage measurer 110 may measure the changed voltage of the node ND.

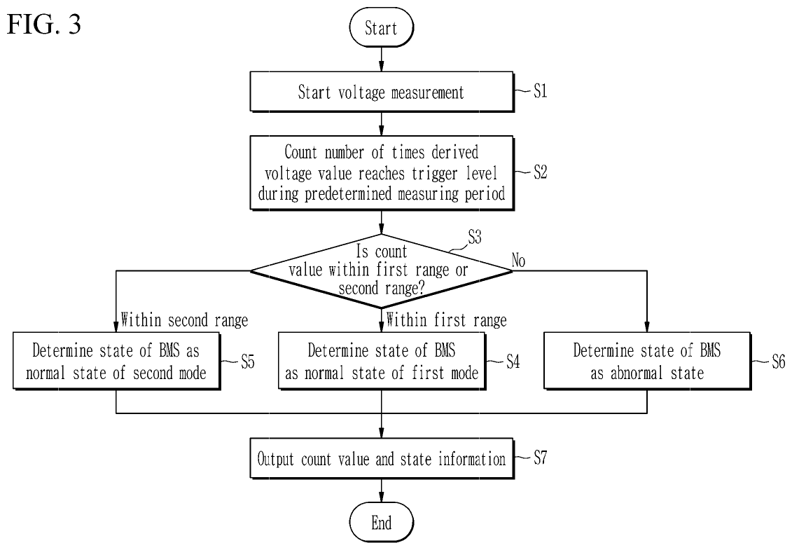

Hereinafter, a method of diagnosing the state of the BMS based on the voltage measured by the diagnostic system 1 will be described in more detail with reference to FIG. 3 to FIG. 5.

FIG. 3 illustrates a flowchart of a diagnostic method according to some embodiments.

The voltage measurer 110 may start measuring the voltage from the node ND (S1), and may transmit the measured voltage signal to the controller 120.

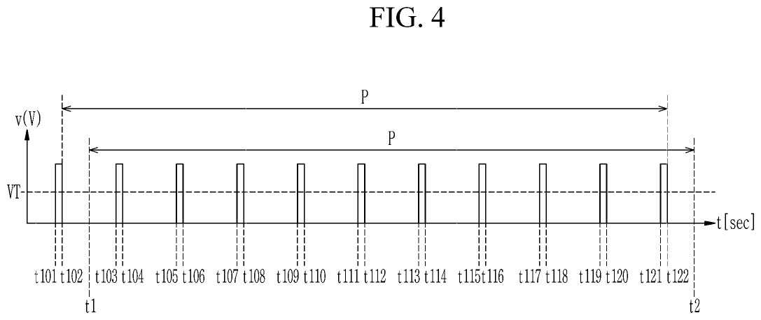

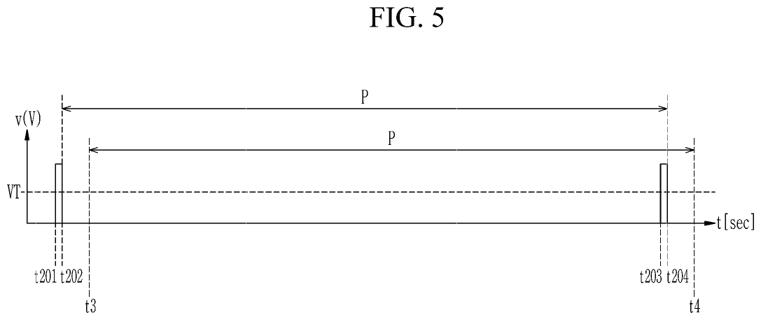

The controller 120 may derive a voltage value based on the voltage signal and count the number of times the derived voltage value reaches the trigger level during a measuring period (e.g., a set or predetermined measuring period) (S2). The controller 120 may generate a value indicating the number of times the trigger level is reached (hereinafter referred to as a “count value”). Hereinafter, steps S2 and S3 will be described in more detail with reference to FIG. 4 and FIG. 5.

FIG. 4 and FIG. 5 illustrate waveform diagrams of the voltage signals derived by the controller in step S2.

The voltage signal may reach a trigger level VT once or more during a measuring period (e.g., a set or predetermined measuring period). The trigger level VT may indicate an arbitrary voltage value among values between highest and lowest values of the voltage values measured during the measuring period (e.g., the set or predetermined measuring period).

According to the waveform diagram shown in FIG. 4, the controller 120 may count the number of times a voltage value v reaches the trigger level VT from a start time point t1 of a measuring period (e.g., a set or predetermined measuring period) P to an end time point t2 of the measuring period P. The voltage value v reaches the trigger level VT at time points t103, t104, t105, t106, t107, t108, t109, t110, t111, and t112. Accordingly, referring to FIG. 4, the count value is 20 times.

In addition, according to the waveform diagram shown in FIG. 5, the controller 120 may count the number of times the voltage value v reaches the trigger level VT from a start time point t3 of the measuring period P to an end time point t4 of the measuring period P. The voltage value v reaches the trigger level VT at time points t203 and t204. Accordingly, referring to FIG. 5, the count value is 2 times.

When the measuring period (e.g., the set or predetermined measuring period) P ends, the controller 120 may determine whether the count value is within the first range or the second range (S3). In the controller 120, information of the first and second periods indicating the measuring cycle of each of the first and second modes may be previously stored. Alternatively, the controller 120 may receive information indicating the first and second periods from the BMS 400 through the communicator 130.

The first range may be a range in which the BMS 400 normally operates corresponding to a case in which the measuring cycle of the BMS 400 is the first period. The first range may be, as shown in Equation 1 below, a range equal to or greater than a value obtained by dividing the measuring period P by the first period and multiplied by 2 and equal to or less than a value obtained by adding 2 to a value obtained by dividing the measuring period P by the first period and multiplied by 2.

$$\\ \begin{matrix}\frac{P}{T 1} * 2 \leq Count < \frac{P}{T 1} * 2 + 2 & ( Equation 1 )\end{matrix}$$

Here, P is a measuring period for counting the number of times, T1 is the first period corresponding to the first mode of the BMS 400, and Count is a value counted by the controller 120. Units of P and T1 may both be seconds.

For example, when the first period T1 is 1 second and the measuring period P is 10 seconds, the first range is a range in which the count value is 20 or more and 22 or less. In the example of FIG. 4, because the count value is 20 times, the controller 120 may determine that the count value is within the first range.

The second range may be a range in which the BMS 400 normally operates corresponding to a case in which the measuring cycle of the BMS 400 is the second period. As shown in Equation 2 below, the second range may be a range equal to or greater than a value obtained by dividing the measuring period P by the second period and multiplied by 2 and equal to or less than a value obtained by adding 2 to a value obtained by dividing the measuring period P by the second period and multiplied by 2.

$$\\ \begin{matrix}\frac{P}{T 2} * 2 \leq Count < \frac{P}{T 2} * 2 + 2 & ( Equation 2 )\end{matrix}$$

Here, P is a measuring period for counting the number of times, T2 is the second period corresponding to the first mode of the BMS 400, and Count is a value counted by the controller 120. Units of P and T2 may both be seconds.

For example, when the second period T2 is 10 seconds and the measuring period P is 10 seconds, the second range is a range in which the count value is 2 or more and 4 or less. In the example of FIG. 5, because the count value is 2 times, the controller 120 may determine that the count value is within the second range.

The reason that the value obtained by adding 2 to the minimum value in each of the first and second ranges is determined as the maximum value is because when the voltage value at the start time point and/or the end time point of the measuring period P is the same as the trigger level, the count value may exceed a value obtained by dividing the measuring period P by the first or second period T1 or T2 even when the BMS 400 is in a normal state.

For example, in FIG. 4, it is assumed that the start time point of the measuring period P is t102 and the end time point of the measuring period P is t122. The voltage value reaches the trigger level VT at time points t102, t103, t104, t105, t106, t107, t108, t109, t110, t111, and t112. Accordingly, the count value is 21 times.

In addition, for example, in FIG. 5, it is assumed that the start time point of the measuring period P is t202 and the end time point of the measuring period P is t204. The voltage value reaches the trigger level VT at time points t202, t203, and t204. Accordingly, the count value is 3 times.

When the count value is within the first range, the controller 120 may determine the state of the BMS 400 as the normal state of the first mode (S4). When the count value is within the second range, the controller 120 may determine the state of the BMS 400 to be the normal state of the second mode (S5). When the count value is not within the first and second ranges, the controller 120 may determine the state of the BMS 400 to be the abnormal state (S6).

A voltage value being above the trigger level may indicate that the BMS is performing a measurement. In the normal state in which the BMS 400 normally operates, because the measuring cycle is the first or second period, the count value is within the first or second range. When the count value is not within the first and second ranges, because the measuring cycle of the BMS 400 is different from the first or second period, the controller 120 may determine that the BMS 400 is in an abnormal state.

In FIG. 3, the state in which the BMS 400 normally operates is illustrated as a normal state of one of the first mode and the second mode, but embodiments according to the present disclosure are not limited thereto. The normal state of the BMS 400 may include respective normal states of two or more modes in which the BMS 400 operates at different cycles.

The controller 120 may determine the state of the BMS 400 through one of steps S4 to S6 and generate a signal indicating the determined state of the BMS 400 (hereinafter referred to as a “BMS state signal”). The BMS state signal may include information indicating a count value. The communicator 130 may transmit the BMS state signal to the output device 200.

The output device 200 may receive the BMS state signal. The output device 200 may output a diagnostic result including a count value and information representing a state of the BMS 400 based on the BMS state signal (S7). The output device 200 may visually output the diagnostic result through a display. The output device 200 may provide a screen displaying the diagnostic result through an application and the like installed in the output device 200.

A user may check the state of the BMS 400 through the output device 200 and, when the BMS 400 is in an abnormal state, may take countermeasures for the abnormal state.

While aspects of some embodiments of the present disclosure have been described in connection with what is presently considered to be practical embodiments, it is to be understood that embodiments according to the present disclosure are not limited to the disclosed embodiments, but, on the contrary, is intended to cover various modifications and equivalent arrangements included within the spirit and scope of the appended claims, and their equivalents.

### DESCRIPTION OF SOME OF THE REFERENCE SYMBOLS

1: diagnostic system
100: measuring device
110: voltage measurer
120: controller
130: communicator
200: output device
3: battery system
300: battery pack
301, 302, 303: battery cell
400: battery management system (BMS)
500: thermistor
600, 601: relay
4: external device

What is claimed is:

1. A measuring device, comprising:
a voltage measurer configured to measure a voltage from a node on a wire connected to a battery management system (BMS); and
a controller configured to receive the measured voltage signal from the voltage measurer to derive a voltage value, to count a number of times the voltage value reaches a reference voltage during a measuring period, and to determine a state of the BMS as one of a normal state of a first mode, a normal state of a second mode, or an abnormal state based on the number of times.

2. The measuring device as claimed in claim 1, wherein
the wire is connected to one end of a thermistor,
the first mode is a power mode in which the BMS is configured to measure a temperature from the thermistor at a cycle of a first period, and
the second mode is a power mode in which the BMS is configured to measure the temperature from the thermistor at a cycle of a second period longer than the first period.

3. The measuring device as claimed in claim 2, wherein
the controller is configured to determine the state of the BMS as the normal state of the first mode based on the number of times being within a first range in which a value obtained by dividing the measuring period by the first period and multiplied by is a minimum value and a value obtained by adding 2 to the minimum value is a maximum value.

4. The measuring device as claimed in claim 3, wherein
the controller is configured to determine the state of the BMS as the normal state of the second mode based on the number of times being within a second range in which a value obtained by dividing the measuring period by the second period and multiplied by 2 is a minimum value and a value obtained by adding 2 to the minimum value is a maximum value.

5. The measuring device as claimed in claim 4, wherein
the controller is configured to determine the state of the BMS as the abnormal state based on the number not being within the first and second ranges.

6. A diagnostic system, comprising:
a measuring device configured to measure a voltage from a node on a wire connected to a battery management system (BMS), to derive a voltage value from the measured voltage signal, to count a number of times the voltage value reaches a reference voltage during a measuring period, and to determine a state of the BMS as one of a normal state of a first mode, a normal state of a second mode, or an abnormal state based on the number of times; and
an output device configured to receive a signal indicating the state of the BMS from the measuring device, and to output a diagnostic result including the state of the BMS based on the signal indicating the state of the BMS.

7. The diagnostic system as claimed in claim 6, wherein
the wire is connected to one end of a thermistor, and
the first mode is a power mode in which the BMS is configured to measure a temperature from the thermistor at a cycle of a first period, and
the second mode is a power mode in which the BMS is configured to measure the temperature from the thermistor at a cycle of a second period longer than the first period.

8. The diagnostic system as claimed in claim 7, wherein
the measuring device is configured to determine the state of the BMS as the normal state of the first mode based on the number of times being within a first range in which a value obtained by dividing the measuring period by the first period and multiplied by 2 is a minimum value and a value obtained by adding 2 to the minimum value is a maximum value.

9. The diagnostic system as claimed in claim 8, wherein
the measuring device is configured to determine the state of the BMS as the normal state of the second mode based on the number of times being within a second range in which a value obtained by dividing the measuring period by the second period and multiplied by 2 is a minimum value and a value obtained by adding 2 to the minimum value is a maximum value.

10. The diagnostic system as claimed in claim 9, wherein
the measuring device is configured to determine the state of the BMS as the abnormal state based on the number not being within the first and second ranges.

11. The diagnostic system as claimed in claim 6, wherein
the output device includes a display configured to visually output the diagnostic result.

12. A diagnostic method, comprising:
measuring a voltage from a node on a wire connected to a battery management system (BMS);
deriving a voltage value based on the measured voltage and counting a number of times the voltage value reaches a reference voltage during a measuring period;
determining whether the number of times is within a first or second range; and
determining a state of the BMS as one of a normal state of a first mode, a normal state of a second mode, or an abnormal state based on the determined result.

13. The diagnostic method as claimed in claim 12, wherein
the wire is a wire connected to one end of a thermistor,
the first mode is a power mode in which the BMS measures a temperature from the thermistor at a cycle of a first period, and
the second mode is a power mode in which the BMS measures the temperature from the thermistor at a cycle of a second period longer than the first period.

14. The diagnostic method as claimed in claim 13, wherein
the first range is a range in which a value obtained by dividing the measuring period by the first period and multiplied by 2 is a minimum value and a value obtained by adding 2 to the minimum value is a maximum value.

15. The diagnostic method as claimed in claim 14, wherein
the determining of the state of the BMS as one of the normal state of the first mode, the normal state of the second mode, or the abnormal state includes
determining, when the number of times is within the first range, the state of the BMS as the normal state of the first mode.

16. The diagnostic method as claimed in claim 13, wherein
the second range is a range in which a value obtained by dividing the measuring period by the second period and multiplied by 2 is a minimum value and a value obtained by adding 2 to the minimum value is a maximum value.

17. The diagnostic method as claimed in claim 16, wherein
the determining of the state of the BMS as one of the normal state of the first mode, the normal state of the second mode, or the abnormal state includes
determining, when the number of times is within the second range, the state of the BMS as the normal state of the second mode.

18. The diagnostic method as claimed in claim 12, wherein
the determining of the state of the BMS as one of the normal state of the first mode, the normal state of the second mode, or the abnormal state includes
determining the state of the BMS as the abnormal state when the number is not within the first or second ranges.

19. The diagnostic method as claimed in claim 12, further comprising
outputting a diagnostic result including the state of the BMS determined as one of the normal state of the first mode, the normal state of the second mode, or the abnormal state.

20. The diagnostic method as claimed in claim 19, wherein
the outputting of the diagnostic result includes visually outputting the state of the BMS and the number of times through a display.
